(19) United States
(12) Patent Application Publication
(10) Pub. No.: US 2016/0148681 A1
(43) Pub. Date: May 26, 2016

(54) PARALLEL FORMING OF MEMORY CELLS

(71) Applicant: INFINEON TECHNOLOGIES AG, Neubiberg (DE)

(72) Inventor: Christoph Bukethal, Dresden (DE)

(21) Appl. No.: 14/548,539

(22) Filed: Nov. 20, 2014

(51) Int. Cl. G11C 13/00; H01L 21/66; H01L 45/00

(52) U.S. Cl. CPC G11C 13/0023; H01L 45/1641; H01L 22/10

(57) ABSTRACT

A method of parallel forming of memory cells, and an apparatus including a memory and a multiplexer. The memory has an array of memory cells and bit lines, wherein each of the bit lines is associated with a plurality of the memory cells. The multiplexer has a plurality of outputs coupled to a plurality of the respective bit lines. The multiplexer is configured to select in parallel a plurality of the bit lines by applying a forming bias voltage, detect formation of one or more memory cells associated with the selected bit lines, and disconnect from the forming bias voltage any formed memory cells.

### BACKGROUND

Resistive random-access memory (RRAM or ReRAM) is a non-volatile memory in which a dielectric that is normally insulating, is configured to conduct after application of a sufficiently high voltage. The forming of a conduction path typically requires a relatively high voltage. Once the path is formed in the dielectric, the path may be “reset” (broken, to provide high resistance) or “set” (re-formed, to provide a low resistance) by an appropriately applied voltage.

When RRAM is first manufactured it is in a high resistance state. Each memory cell in an RRAM array is subjected to a forming process once at the beginning of life in order to be put into a lower resistance state. This forming process may be performed in a factory after the memory is manufactured. During the forming process, a relatively high voltage is applied to each of the RRAM memory cells until the memory cells transition from the high resistive state to a low resistive state. Some forming techniques take a long time to complete as every memory cell requires a different time/voltage to be formed. Once a RRAM memory cell is formed the applied forming bias voltage should be switched off immediately.

The forming bias voltage may be applied via bit lines using respective assembly buffers. The number of assembly buffers is limited due to a limited amount of available space. The option of forming parallelism, that is, forming a plurality of cells in parallel, is limited by the number of assembly buffers. This relatively small forming parallelism results in significant forming times, long test times, and high test cost during frontend and backend tests.

### BRIEF DESCRIPTION OF THE DRAWINGS

FIG. 1 illustrates schematic diagram of an apparatus in accordance with an exemplary embodiment.

FIG. 2 is a flowchart of a method in accordance with an exemplary embodiment.

FIG. 3A is circuit diagram of a portion of a multiplexer of the apparatus of FIG. 1.

FIG. 3B is a graph of I_{OUT} versus V_{IN} of a memory cell supplied via the multiplexer of FIG. 2A.

FIG. 4 is a flowchart of a method in accordance with another exemplary embodiment.

### DETAILED DESCRIPTION

The present disclosure is directed to increasing memory cells formed in parallel. This is accomplished by using a multiplexer to apply a forming bias voltage to a plurality of bit lines in parallel, and then disconnecting formed memory cells from the forming bias voltage. If the number of memory cells formed in parallel increases by factor N, then the overall memory array forming time decreases by the factor of 1/N.

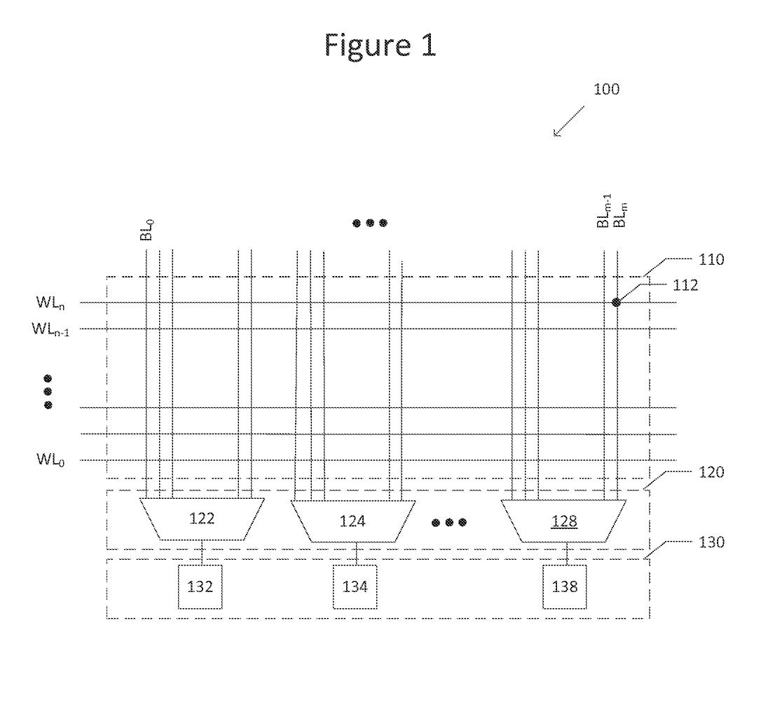

FIG. 1 illustrates schematic diagram of an apparatus 100 in accordance with an exemplary embodiment. The apparatus 100 comprises a memory 110, multiplexers 120 (shown as comprised of 122, 124 . . . 128), and assembly buffers 130 (shown as comprised of 132,134 . . . 138).

The memory 110 has an array of memory cells 112 formed at intersections of word lines WL₀-WLₙ and bit lines BL₀-BLₘ. For the sake of convenience, in the figure only one memory cell 112 is referenced.) A digital data value may be stored as a memory resistance (high or low). The memory state of a memory cell can be read by supplying appropriate voltages to the bit line BLₘ and word line WLₙ associated with to the selected memory cell 112. The resistance or memory state can be read as an output voltage or current of the bit line BL₀-BLₘ coupled to the selected memory cell. One resistance state may correspond to a data “0,” for example, while the other resistance state may correspond to a data “1.”

Each of the multiplexers 120 comprises a plurality of outputs coupled to a plurality of bit lines BL. The assembly buffers 130 are not coupled directly to the bit lines BL, but rather each assembly buffer 130 has an output coupled to an input of one of a respective one of the multiplexers 120 to provide a supply voltage. When data is to be written to a memory cell 112, the data represented by a “0” or a “1” is loaded into the assembly buffer 130, and the assembly buffer 130 then applies a voltage level based on the data to the memory cell 112. The assembly buffer 130 may form a portion of a sense amplifier.

The disclosure is not limited to the number of word lines WL, bit lines BL, multiplexers 120 and assembly buffers 130 shown. There may be any number of each of these elements as suitable for the intended purpose.

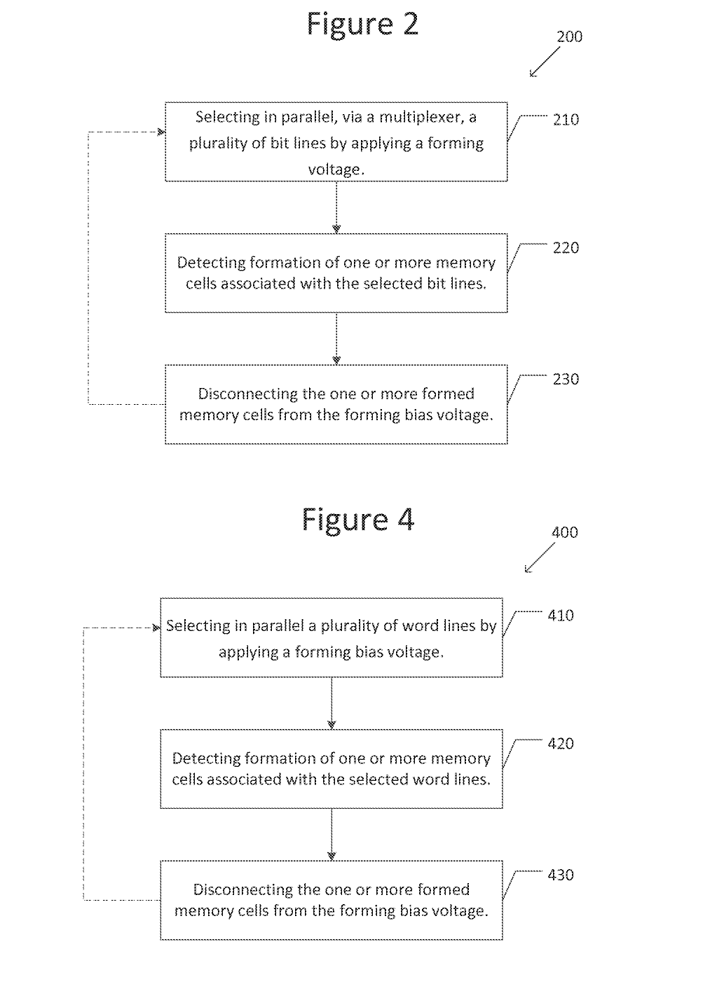

FIG. 2 is a flowchart 200 of a method in accordance with an exemplary embodiment.

The process of forming memory cells in accordance with this disclosure comprises three steps: (1) Parallel selection of a plurality of bit lines; (2) Detection of successful formation of memory cells; and (3) Disconnection of formed memory cells from a forming bias voltage. These steps are described in detail below.

Parallel Selection of a Plurality of Bit Lines:

At Step 210, a plurality of bit lines BL for a single assembly buffer 130 is selected in parallel, via a multiplexer 120, by applying a forming bias voltage. The forming bias voltage is output by the assembly buffer 130, and the multiplexer 120 connects the bias forming voltage to the selected bit lines BL. The forming bias voltage may be a continuously ramped voltage, for example, 0.25V per 1 msec.

The multiplexer 120 may select all of its associated bit lines BL in parallel. Alternatively, the multiplexer 120 may select all of its even bit lines BLs, odd bit lines BLs, or any combination of bit lines BL suitable for the intended purpose.

Detection of Successful Formation of Memory Cells:

Next, at Step 220, the formation of one or more memory cells 112 associated with the selected bit lines BL is detected. This detection may occur when a voltage of a respective memory cell 112 is less than a reference voltage, that is, when the resistance of the memory cell 112 changes from insulator to conductor. Similarly, this detection may occur when a current of a bit line BL associated with the memory cell(s) 112 is greater than a threshold current I_{Th}.

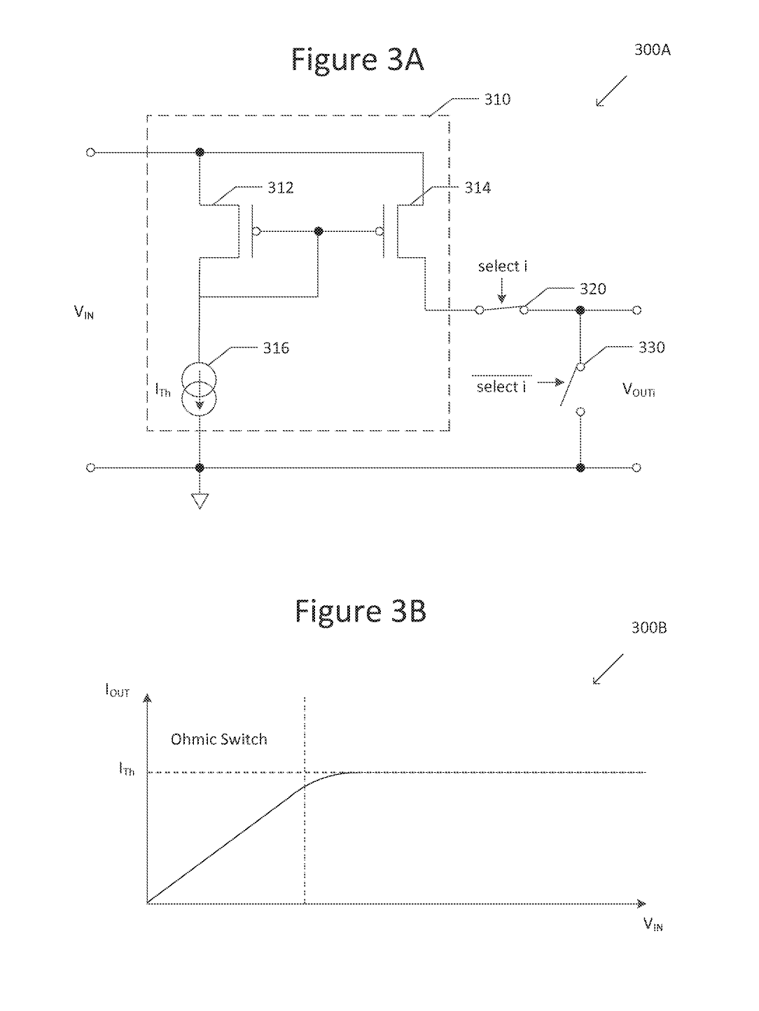

FIG. 3A is circuit diagram 300A of a portion of a multiplexer 120 of the apparatus of FIG. 1. FIG. 3B is a graph of I_{OUT} versus V_{IN} of the portion of a memory cell 112 supplied via the multiplexer of FIG. 3A.

The multiplexer 120 comprises a clipping circuit 310, a first switch 320 and a second switch 330. The first and second switches 320, 330 are standard in a multiplexer and determine whether the multiplexer's input is connected to its output. In the positons shown in the figure, the multiplexer's input voltage V_{IN} is connected to its output voltage V_{OUTi}. “OUTi” reflects that the multiplexer 120 has multiple outputs. The circuit 300A shown represents one circuit for each output of the multiplexer 120, that is, for each bit line BL.

The clipping circuit 310 is configured to limit a current supplied to the memory cells 112 associated with the respective bit line BL to a threshold current I_{Th}. If the current were not limited, the current would increase to a value that might destroy the memory cells 112.

The clipping circuit 310 comprises a first PMOS transistor 312, a second PMOS transistor 314, and a current source 316. The first PMOS transistor 312 has a source coupled to an input voltage V_{IN}. The current source 316 has a first terminal coupled between the drain of the first PMOS transistor 312 and a second terminal coupled to ground, and is configured to define the maximum current I_{Th} which can be consumed by the memory cells 112 associated with the bit line BL. The second PMOS transistor 314 has a source coupled to the input voltage V_{IN} and a drain coupled to an output voltage V_{OUTi}. The gates of the first and second transistors 312, 314 are coupled together and to the first terminal of the current source 316. The second PMOS transistor 314 is configured to limit the current supplied to the memory cells 112 associated with the bit line BL to the threshold current I_{Th}.

The clipping circuit 320 is illustrated as being comprised of PMOS transistors, but may be alternatively comprised of NMOS transistors. As is known, a PMOS transistor source is connected to a voltage source. In order to allow current to flow, the gate needs to be pulled to ground, and to turn the current off the gate needs to be pulled to the voltage source.

When the forming is successful at one or more memory cells 112, as shown in FIG. 3B, the current I_{OUT} on the associated bit line BL increases quickly. The current must be clipped at the threshold current I_{Th} to prevent the formed memory cells 112 from becoming damaged. Also, the assembly buffer 130 may be configured to sense, through the multiplexer 120, when a current on a bit line BL is greater than or equal to the threshold current I_{Th}. When the assembly buffer 130 detects this current increase, it may ramp down the forming bias voltage automatically or send feedback to the processor (not shown) to interrupt the operation and ramp down the forming bias voltage.

Alternatively, the current clipping could be performed by the assembly buffer 130, and the sensing may be performed by the multiplexer 120 in a manner appreciated by those skilled in the art.

Disconnection of Formed Memory Cells from Forming Bias Voltage:

At Step 230, the one or more formed memory cells is disconnected from the forming bias voltage. More specifically, when one or more of the memory cells 112 is detected as having been successfully formed, a read operation is performed under the control of the processor to determine the specific memory cell(s) 112 that were formed and are disconnected by active addressing.

Finally, Steps 210, 220, and 230 may be repeated on any non-formed memory cells until forming of the memory array 1120 is completed. The criteria for completion could be when all of the memory cells 112 have formed, when a significant enough number of memory cells 112 have formed, a certain time period has elapsed, or any other criteria suitable for the intended purpose.

FIG. 4 is a flowchart 400 of a method in accordance with another exemplary embodiment. The method of FIG. 4 differs from that of FIG. 2 in that rather than a parallel selection of bit lines, there is a parallel selection of word lines.

At Step 410, any of a plurality of word lines WL may be selected in parallel by a word line decoder by applying a forming bias voltage.

Next, at Step 420, formation of one or more memory cells 112 associated with the selected word lines WL may be detected. The current increase cannot be sensed at the word line WL, but must instead be performed at the bit line BL. At any bit line BL current increase detection, the processor interrupts the sequence and actively looks at the different word lines WLs where the current increase occurred to determine which of the memory cells 112 formed. This can be accomplished by the processor using a standard read process. The processor may deselect the word line WL where the current increase occurred and select all of the other word lines WL. This takes more overhead as compared with the parallel selection of bit lines BL, but is another option for increasing parallelism.

At Step 430, the one or more formed memory cells 112 is deselected from the forming bias voltage. The disconnection may be performed by a word line selection device (not shown), or alternatively, by a processor via active addressing.

Finally, Steps 410, 420, and 430 may be repeated on any non-formed memory cells until forming of the memory array 1120 is completed. The criteria for completion could be when all of the memory cells 112 have formed, when a significant enough number of memory cells 112 have formed, a certain time period has elapsed, or any other criteria suitable for the intended purpose.

The memory 110 may be a resistive random access memory (RRAM), though the disclosure is not necessarily limited in this respect.

While the foregoing has been described in conjunction with exemplary embodiment, it is understood that the term “exemplary” is merely meant as an example, rather than the best or optimal. Accordingly, the disclosure is intended to cover alternatives, modifications and equivalents, which may be included within the scope of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This disclosure is intended to cover any adaptations or variations of the specific embodiments discussed herein.

1. An apparatus, comprising:
a memory having an array of memory cells and bit lines, wherein each of the bit lines is associated with a plurality of the memory cells; and
a multiplexer having a plurality of outputs coupled to a plurality of the respective bit lines, and configured to select in parallel a plurality of the bit lines by applying a forming bias voltage.

2. The apparatus of claim 1, further comprising:
an assembly buffer having an output coupled to an input of the multiplexer.

3. The apparatus of claim 1, wherein the multiplexer is further configured to:
detect formation of one or more memory cells associated with the selected bit lines; and
disconnect from the forming bias voltage any formed memory cells.

4. The apparatus of claim 1, wherein the memory is a resistive random access memory (RRAM).

5. The apparatus of claim 1, wherein the multiplexer comprises, for each of the bit lines coupled to the multiplexer, a clipping circuit configured to limit a current supplied to the memory cells associated with a respective bit line to a threshold current.

6. The apparatus of claim 5, wherein the clipping circuit comprises:
a first transistor having a first source or a first drain coupled to an input voltage of the multiplexer;
a current source having a first terminal coupled between the other of the source or drain of the first transistor and a second terminal coupled to ground, and configured to define the maximum current which can be consumed by the memory cells associated with the respective bit line; and
a second transistor having a second source or a second drain coupled to the input voltage of the multiplexer and the other of the source or drain coupled to an output voltage, and configured to limit the current supplied to the memory cells associated with the respective bit line to the threshold current,
wherein gates of the first and second transistors are coupled together and to the first terminal of the current source.

7. The apparatus of claim 6, wherein the first and second transistors are PMOS transistors.

8. The apparatus of claim 5, wherein an input of the multiplexer is coupled to a voltage supply.

9. The apparatus of claim 5, further comprising:
an assembly buffer having an output coupled to an input of the multiplexer, and configured to sense when a current on a bit line is greater than or equal to the threshold current.

10. The apparatus of claim 1, further comprising a plurality of multiplexers, wherein each of the plurality of multiplexers has a plurality of outputs coupled to a plurality of the respective bit lines, and is configured to select in parallel a plurality of the bit lines by applying a forming respective bias voltage.

11. A method of forming a memory having an array of memory cells and bit lines, wherein each of the bit lines is associated with a plurality of the memory cells, the method comprising:
selecting in parallel, via a multiplexer, a plurality of bit lines by applying a forming bias voltage;
detecting formation of one or more memory cells associated with the selected bit lines; and
disconnecting the one or more formed memory cells from the forming bias voltage.

12. The method as claimed in claim 11, wherein the detecting step comprises:
detecting formation of the one or more memory cells when a voltage of each of the one or more memory cells is less than a reference voltage.

13. The method as claimed in claim 12, wherein the detecting step is performed by an assembly buffer coupled to an input of the multiplexer.

14. The method as claimed in claim 12, wherein the detecting step is performed by the multiplexer.

15. The method as claimed in claim 11, further comprising:
repeating the selecting, detecting, and disconnecting steps on any non-formed memory cells.

16. The method as claimed in claim 11, wherein the disconnecting step is performed by the multiplexer.

17. The method as claimed in claim 11, wherein the disconnecting step is performed by active addressing.

18. The method as claimed in claim 11, wherein the memory array is a resistive random access memory (RRAM) array.

19. A method of forming a memory array having word lines, wherein each of the word lines is associated with memory cells, the method comprising:
selecting in parallel a plurality of word lines by applying a forming bias voltage;
detecting formation of one or more memory cells associated with the selected word lines; and
disconnecting the one or more formed memory cells from the forming bias voltage.
